(19) United States
(12) Patent Application Publication
(10) Pub. No.: US 2008/0055577 A1
(43) Pub. Date: Mar. 6, 2008

(54) Lithographic apparatus and method

(75) Inventors: Erik Marie Jose Smeets, Prinsenbeek (NL); David Christopher Ockwell, Waalre (NL); Johannes Arie Van Den Broek, Heeze (NL)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 11/512,435

(22) Filed: Aug. 30, 2006

(51) Int. Cl. G03F 7/20; G03B 27/42

(52) U.S. Cl. 355/53; 430/311; 430/396

(57) ABSTRACT

According to an aspect of the present invention, there is provided a method of projecting a pattern onto a substrate. The method includes rotating a mask having a plurality of patterns provided thereon, to select a pattern to be projected onto a substrate, using the selected pattern to impart a beam of radiation with a pattern in its cross-section corresponding to the selected pattern, and projecting the patterned beam of radiation onto a target portion of the substrate.

### FIELD

The present invention relates to a lithographic apparatus and method.

### BACKGROUND

Integrated circuits (ICs) are usually manufactured using lithography. A patterning device, which is alternatively referred to as a mask or a reticle, may be used to generate a circuit pattern corresponding to an individual layer of the IC. This pattern can be imaged onto a target portion (e.g. comprising part of, one or several dies) on a substrate (e.g. a silicon wafer) that has a layer of radiation-sensitive material (resist). In general, a single substrate will contain a network of adjacent target portions that are successively exposed.

Typically, a multiplicity of layers are provided on a substrate, each layer being processed to permanently fix the pattern in that layer before the next layer is formed. Once all of the layers have been formed and processed, the substrate is cut up into individual ICs and each IC is mounted on an interstitial board. Each interstitial board is typically provided with legs which are electrically connected to the IC, thereby allowing electrical signals to pass to and from the IC. The interstitial board and IC are then covered in plastic, and may then be attached to a printed circuit board.

It has been conventional to use wires to connect an IC to an interstitial board. However, in recent years the distance between locations to which wires are to be bonded has become progressively smaller, and it has become more difficult to use wire bonding. A process which is known as flip-chip bumping is increasingly used to connect ICs to interstitial boards instead of using connection wires. In flip-chip bumping, solder (or some other metal) is provided at specific locations on each IC. The IC is inverted and bonded to an interstitial board. The IC is bonded to the interstitial board by heating the solder such that it melts, and then allowing it to cool.

A lithographic apparatus may be used to apply a pattern of solder bump locations on the substrate, i.e. a lithographic apparatus may be a flip-chip bumping apparatus. The bump location pattern is applied to the substrate using a lithography mask. However, the costs of masks can be expensive, particularly when a large number of masks are required. The expense associated with the masks increases the costs associated with using a lithographic apparatus to apply solder bump patterns to a substrate.

### SUMMARY

According to a first aspect of the present invention, there is provided a method of projecting a pattern onto a substrate, comprising:

rotating a mask having a plurality of patterns provided thereon, to select a pattern to be projected onto a substrate;

using the selected pattern to impart a beam of radiation with a pattern in its cross-section corresponding to the selected pattern; and

projecting the patterned beam of radiation onto a target portion of the substrate.

According to a further aspect of the present invention, there is provided a lithographic apparatus, comprising:

a support configured to support a patterning device, the patterning device arranged to impart a beam of radiation with a pattern in its cross section;

a projection system configured to project the patterned beam onto a target portion of a substrate; and

a rotational mechanism configured to rotate the patterning device.

According to a further aspect of the present invention, there is provided a mask carrier, the mask carrier being formed from a container provided with a plurality of slots to load or unload a mask into or out of the mask carrier.

According to a further aspect of the present invention, there is provided a lithographic mask comprising more than two patterns.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 schematically shows a lithographic apparatus;

FIG. 2 is a flow diagram which represents flip-chip bumping;

FIG. 3 depicts a mask used in flip-chip bumping;

FIGS. 4a and 4b depict masks used in flip-chip bumping according to an embodiment of the present invention;

FIG. 5 depicts different possible positions of a mask in and around a lithographic apparatus;

FIG. 6 depicts a mask carrier according to an embodiment of the present invention; and

FIGS. 7a to 7e depict operating principles of an embodiment of the present invention.

### DETAILED DESCRIPTION

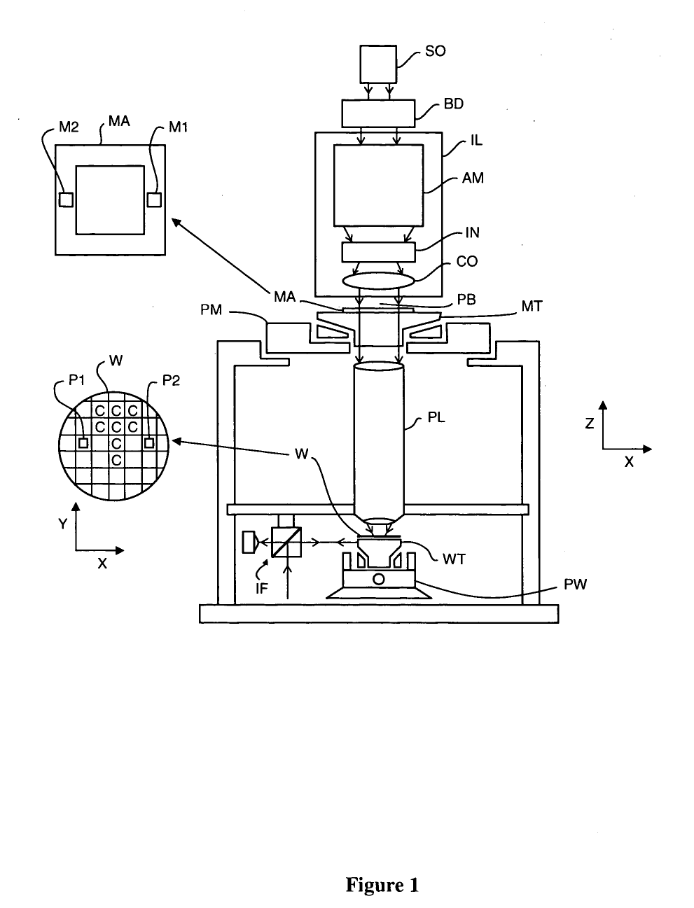

FIG. 1 schematically depicts a lithographic apparatus. The apparatus comprises:

an illumination system (illuminator) IL configured to provide a beam PB of radiation (e.g. UV radiation or EUV radiation);

a first support structure (e.g. a mask table) MT configured to hold a patterning device (e.g. a mask) MA and connected to a first positioner PM configured to accurately position the patterning device with respect to item PL;

a substrate table (e.g. a wafer table) WT configured to hold a substrate (e.g. a resist-coated wafer) W and connected to a second positioner PW configured to accurately position the substrate with respect to item PL; and

a projection system (e.g. a refractive projection lens) PL configured to project a pattern imparted to the beam PB by patterning device MA onto a target portion C (e.g. comprising one or more dies) of the substrate W.

As here depicted, the apparatus is of a transmissive type (e.g. employing a transmissive mask). Alternatively, the apparatus may be of a reflective type (e.g. employing a programmable mirror array of a type as referred to above).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases the source may be integral part of the apparatus, for example when the source is a mercury lamp. The source SO and the illuminator IL, together with the beam delivery system BD if required, may be referred to as a radiation system.

The illuminator IL may comprise adjusting means AM for adjusting the angular intensity distribution of the beam. Generally, at least the outer and/or inner radial extent (commonly referred to as σ-outer and σ-inner, respectively) of the intensity distribution in a pupil plane of the illuminator can be adjusted. In addition, the illuminator IL generally comprises various other components, such as an integrator IN and a condenser CO. The illuminator provides a conditioned beam of radiation having a desired uniformity and intensity distribution in its cross-section.

The beam PB is incident on the patterning device MA, which is held on the support structure MT. Having traversed the patterning device MA, the beam PB passes through the projection system PL, which focuses the beam onto a target portion C of the substrate W. With the aid of the second positioner PW and position sensor IF (e.g. an interferometric device), the substrate table WT can be moved accurately, e.g. so as to position different target portions C in the path of the beam PB. Similarly, the first positioner PM and another position sensor (which is not explicitly depicted in FIG. 1) can be used to accurately position the patterning device MA with respect to the path of the beam PB, e.g. after mechanical retrieval from a mask storage area (e.g. a mask library), or during a scan. Patterning device MA and substrate W may be aligned using patterning device alignment marks M1, M2 and substrate alignment marks P1, P2.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. In this manner, the reflected beam is patterned.

Following projection of the pattern onto the substrate W, the substrate is processed. This is generally done in a track: a tool that develops the exposed resist (the track may also apply a layer of resist to the substrate before lithographic exposure). The developed resist is then further processed to provide the developed layer with desired electrical properties (for example by filling recesses of the pattern with a suitable semiconductor or metal). A multiplicity of layers are provided in this manner, the layers together form an integrated circuit (IC). The term ‘substrate’ used herein is intended to include a substrate that already contains multiple processed layers.

Once the ICs have been formed on the substrate, the substrate is usually passed to a packaging foundry. The packaging foundry includes apparatus which may be used to package individual ICs provided on the substrate. Each IC is mounted on a board which has ‘legs’ that are electrically connected to the IC. One way in which this may be done is by using solder bumps to provide connections to the IC, in a process which is referred to as flip-chip bumping.

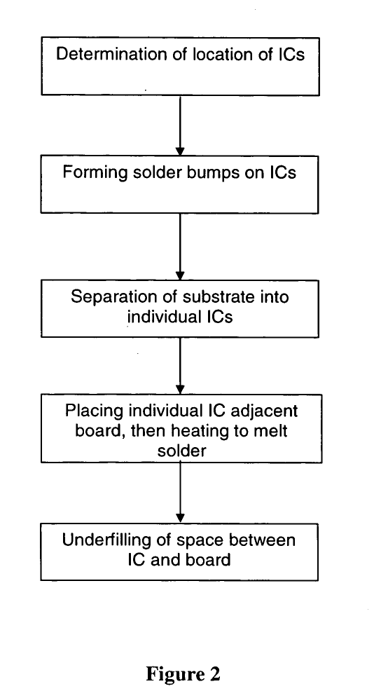

A flow chart which summarizes a conventional flip-chip bumping process is shown in FIG. 2. The first step of the flip-chip process is to determine the locations of the ICs on the substrate. Following this, solder bumps are formed on the ICs. The solder bumps may be formed in part, for example, by lithography using the apparatus shown schematically in FIG. 1. The mask MA is provided with a pattern which comprises the desired location of the solder bumps. This pattern is imaged onto a thick layer of resist (i.e. thicker than a layer of resist used in conventional lithography) which is provided on the substrate. The substrate is then removed from the lithography apparatus and passed to processing apparatus. The resist is then developed and processed such that recesses are formed at the locations where solder bumps are required. Solder is then electroplated in the recesses in the resist. The resist is then removed, so that solder bumps project upwards from the uppermost surface of the substrate.

In general, the resolution of the lithographic apparatus may be low, since the accuracy with which the solder bumps need to be located is typically around 1 micron (this is a significantly lower accuracy than the accuracy of tens of nanometers that is provided by high resolution lithographic apparatus). It will be appreciated that this description is not intended to be limited to any specific resolution (or range of resolutions).

In the next step of the process, the substrate is cut up into individual ICs. This is done by cutting along specially provided tracks, known as scribe lanes, provided between the ICs.

A board is brought into contact with the solder bumps of a given IC, and the board and IC are heated so that the solder bumps melt and adhere to the board (the solder bumps continue to adhere to the IC). This provides a mechanical and electrical connection between the IC and the board. The heating may be performed, for example, by using a furnace. This part of the process may also include inverting the IC such that the solder bumps are located beneath the IC (the board being located beneath the solder bumps).

In the final step of the flip-chip process the space between the IC and the board (i.e. a gap defined by the height of the solder bumps) is filled with an adhesive or some other suitable material. This is known as underfilling and provides mechanical strength, in addition to protecting the solder bumps from moisture or other possibly damaging aspects of the surrounding environment.

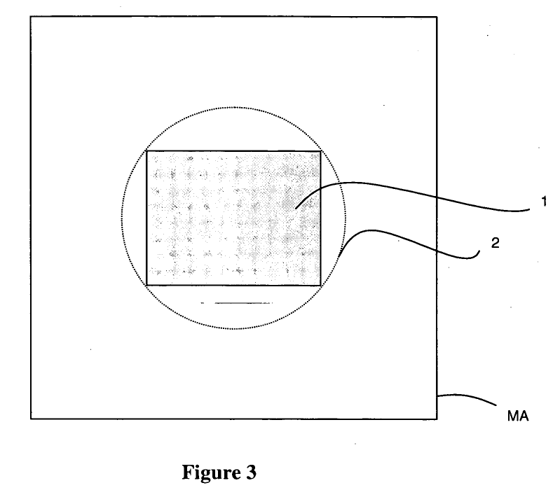

FIG. 3 shows a mask MA which may be used to project a pattern of solder bump locations onto a substrate (not shown in FIG. 3). The mask MA is provided with a patterned area 1 which contains the pattern to be projected onto the substrate. The mask MA is positioned such that the patterned area 1 substantially fills the projected periphery (e.g., circumference) 2 of the projection system of the lithographic apparatus (PL in FIG. 1). This ensures that the entire pattern is imaged onto the substrate, while using the maximum amount of available radiation to expose the pattern on the substrate.

It can be seen from FIG. 3 that the patterned area 1 of the mask MA is located in the center of the mask MA. It can also be seen that the patterned area 1 takes up less than a quarter of the available area of the mask MA. In high resolution lithography, the majority of the mask MA would be filled with a patterned area to be exposed onto a substrate. The image formed by the patterned area would be de-magnified (for example, by a factor of four or five) before being projected onto a substrate in order to apply a high resolution pattern to the surface of a substrate. However, in flip-chip bumping, where the resolution is relatively low, de-magnification is not required. Therefore, a small patterned area 1 is sufficient, and no de-magnification is required. Hence, the patterned area 1 which appears on the mask MA will be directly projected onto the surface of a substrate without de-magnification. This is why only a small area of the mask is used to form the patterned area 1.

The fact that the patterned area 1 takes up only a small fraction of the available area on the mask MA has one or more consequences. Firstly, much of the surface of the mask MA is not used, in that it is not being used to apply a pattern to the substrate. Furthermore, since only a single patterned area 1 appears on each mask MA, a large number of masks MA are required if a large number of patterns are needed.

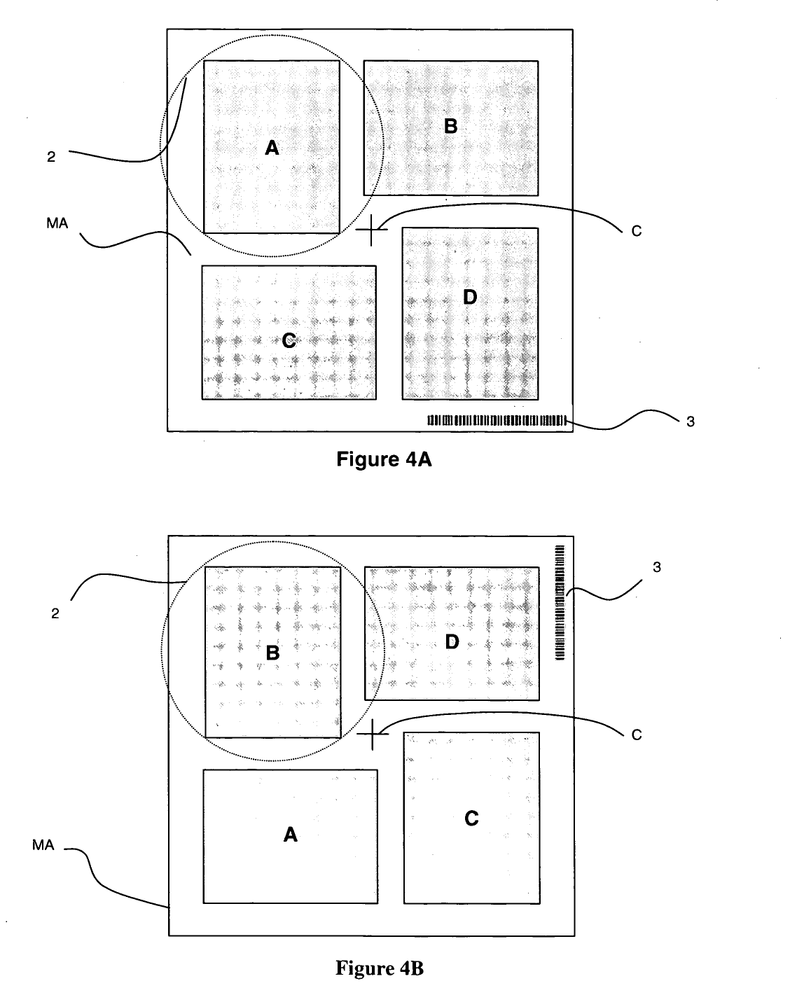

FIG. 4a illustrates an improved mask MA which is provided with four patterned areas A, B, C, D. Each of the patterned areas A, B, C, D is provided with a different pattern to be projected onto the substrate. The patterned areas A, B, C, D are arranged such that the majority of the surface of the mask MA is patterned. By providing a plurality of patterned areas A, B, C, D on a single mask MA, and by providing them in a tightly packed configuration, a disadvantage of the mask of FIG. 3 is overcome. For example, since most of the area of the mask MA is patterned, there is a greatly reduced unused (i.e. un-patterned) area. Furthermore, a plurality of patterns are provided on a single mask. The mask MA of FIG. 4a reduces costs, since less masks MA are needed to provide a plurality of different patterns. Similarly, storage space is saved, since less masks MA need to be stored in order to provide a plurality of patterns. Furthermore, using the mask MA of FIG. 4a may save time, since the mask MA need only be rotated to change the pattern applied to the substrate, as opposed to having to exchange the mask in use for a different suitable mask located in a mask storage area. Rotation of the mask is described in more detail below.

As can be seen from FIG. 4a, the mask MA is positioned such that the projected periphery 2 of the projection system of the apparatus of FIG. 1 is not located at the center C of the mask MA, but is offset from the center C. Specifically, the mask MA is positioned such that only one patterned area (for example, patterned area A) is positioned within the projected periphery 2 of the projection system such that only this pattern is projected onto the substrate. Similarly, the patterned areas A, B, C, D are also located about and offset from the center C of the mask MA.

An identifier 3 (e.g. a bar code) is provided on a non-patterned region of the mask MA. The identifier 3 may be read by the lithographic apparatus so that the lithographic apparatus can determine where each patterned area A, B, C, D is on the mask MA. In an embodiment, a single identifier could be used for all the patterned areas A, B, C, D, or a separate identifier could be used for each patterned area A, B, C, D. The identifier 3 may provide information on the locations of the patterned areas A, B, C, D or direct the lithographic apparatus to where the information can be located. Further, the identifier 3 may comprise, or direct the lithographic apparatus to, other information about the patterned areas A, B, C, D, such as information about the nature of the patterns themselves (e.g. an identifier unique to each different pattern).

In order to project a different patterned area A, B, C, D onto the substrate, the mask MA is rotated-about its center. For example, it can be seen that by rotating the mask MA 90° in an anticlockwise direction, patterned area B is located within the projected periphery 2 of the projection system, and is projected onto the substrate. FIG. 4B illustrates the situation where the mask MA of FIG. 4a has been rotated anticlockwise by 90°. It will be understood that any of the patterned areas A, B, C, D can be selected for projection onto the substrate by appropriate rotation of the mask MA.

The mask MA may be rotated while it is located on the support structure MT (shown in FIG. 1). However, such rotation may not be possible or practical in a standard lithographic apparatus. Therefore, the mask MA may need to be rotated in some other location.

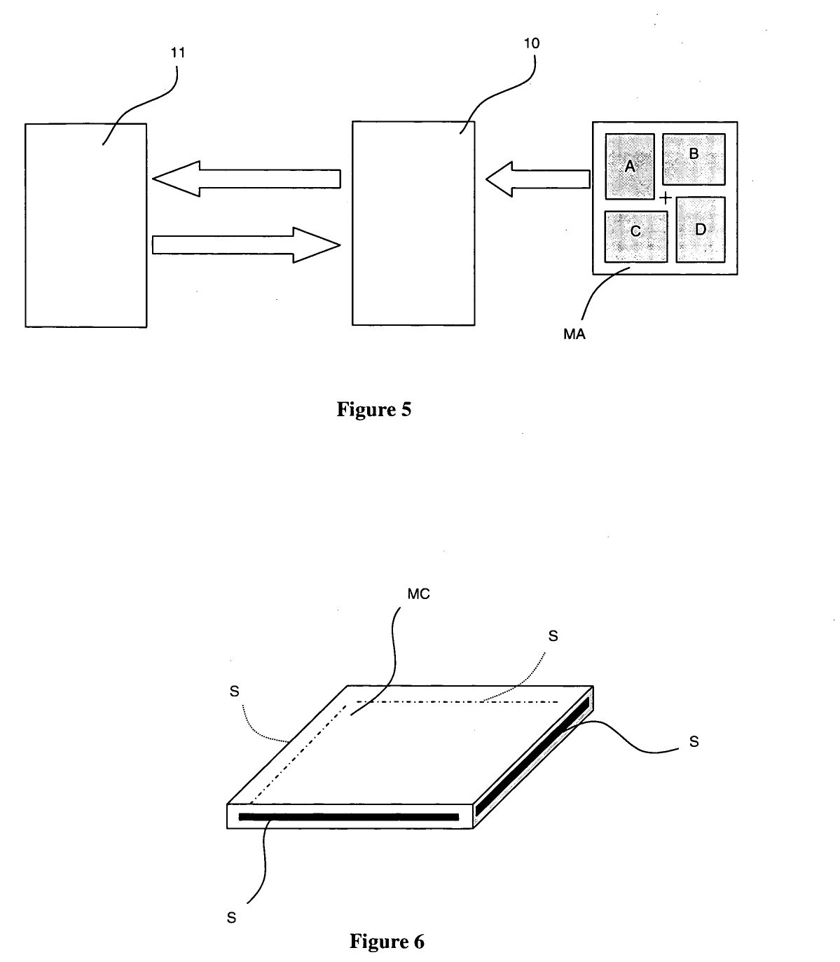

FIG. 5 schematically depicts the various locations of a mask MA when in use. A plurality of masks MA are held in a mask storage area 10 (e.g. a mask library). A suitable mask MA is taken from the mask storage area 10 and loaded into a lithographic apparatus 11 (shown in more detail in FIG. 1). When the mask MA is no longer required (e.g. when a new mask MA is required), the mask which is located in the lithographic apparatus 11 is unloaded from the lithographic apparatus 11, and passed back to the mask storage area 10.

It can be seen from FIG. 5 that there are a variety of locations to rotate the mask MA to select a desired patterned region A, B, C, D. For example, the mask MA could be rotated: before it is loaded into the mask storage area 10; while it is stored in the mask storage area 10; while it is being transferred between the mask storage area 10 and the lithographic apparatus 11; or when it is in the lithographic apparatus 11 (e.g. the mask MA may be rotated while on the support structure MT, as described above).

By rotating the mask MA when it is being transferred from the mask storage area 10 to the lithographic apparatus 11, the mask storage area 10 and the lithographic apparatus 11 do not need to be modified, i.e. lithographic apparatus 11 and mask storage area 10 may be standard apparatus.

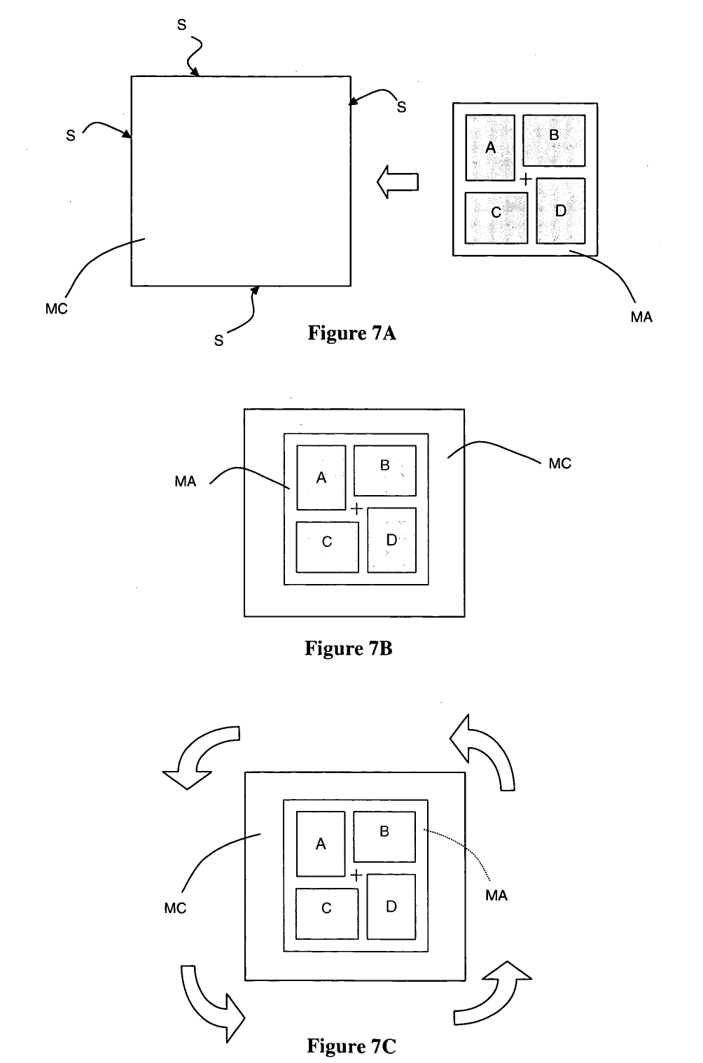

In a standard lithographic apparatus, a mask MA is unloaded from the mask storage area 10 and placed into a mask carrier, in which the mask is carried to the lithographic apparatus 11, where it is unloaded to be used in subsequent exposures. FIG. 6 illustrates a mask carrier MC which facilitates rotation of the mask according to an embodiment of the present invention. The mask carrier MC is similar to a standard mask carrier, for example Standard Mechanical Interface (SMIF) Pod. A standard mask carrier is a container with a slot in one of its sides for loading and unloading a mask from the mask carrier. The mask carrier MC of FIG. 6 is different from a standard mask carrier, in that the mask carrier of FIG. 6 comprises a plurality of slots, and in particular a slot in each of its four sides. Because the mask carrier MC has a plurality of slots S, the mask carrier can be rotated and the mask MA extracted from any side of the mask carrier. This facilitates easy rotation of the mask MA.

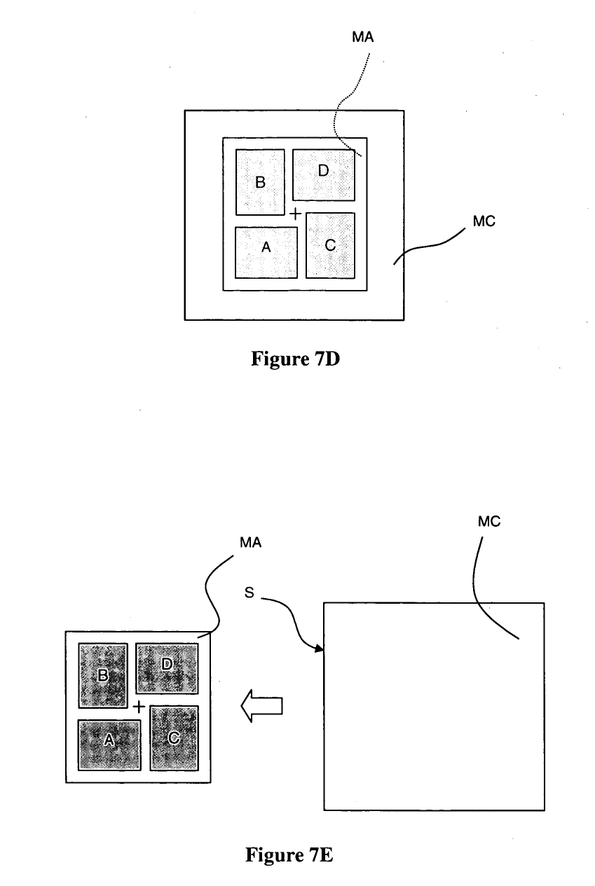

FIGS. 7a to 7e illustrate how the mask carrier MC of FIG. 6 facilitates easy rotation of the mask MA. In FIG. 7a, the mask MA is loaded into the mask carrier MC through one of its slots S, i.e., the right-hand slot depicted in FIG. 7a. The mask MA may be loaded from the mask storage area 10 of FIG. 5. FIG. 7b shows the mask MA loaded inside the mask carrier MC. FIG. 7c shows the mask carrier MC being rotated 90° in an anticlockwise direction. The mask carrier MC may be rotated by a robot handler which could also be used to move the mask carrier MC and mask to the lithographic apparatus 11. Alternatively, the mask carrier MC may be rotated by any suitable apparatus (i.e. any rotational mechanism), or by a user holding the mask carrier. FIG. 7d shows the mask carrier MC and mask MA when they have both been rotated by 90° in an anti-clockwise direction relative to the orientation shown in FIG. 7b. FIG. 7e shows the mask MA being unloaded from the mask carrier MC through one of its slots S, different from the slot through which the mask MA was loaded into the mask carrier MC. The mask MA is then subsequently loaded into the lithographic apparatus 11, for example being located on the support structure MT as shown in FIG. 1.

It can be seen from FIG. 7e that since the mask carrier has slots located around its periphery, the mask MA may be rotated to any desired extent, in order to select any of the patterned areas A, B, C, D to be projected onto the substrate. Since there are a plurality of slots located in the mask carrier MC, the mask MA may be retrieved from the mask carrier MC at any one of these slots. Therefore, the loading and unloading processes where the mask MA is unloaded from the mask storage area 10 and loaded into the lithographic apparatus 11 (or vice versa) remains unchanged. Specifically, rotation of the mask MA is transparent to the loading and unloading mechanisms used in the lithographic apparatus 11 and the mask storage area 10.

If, after using the mask MA to project a specific pattern of bump locations onto the substrate, a different pattern is required, the mask MA can be rotated again (or replaced with another mask). The mask MA can be removed from the support structure MT, rotated, and then replaced back onto the support structure MT. Rotation of the mask MA may be undertaken when the mask MA is in the mask carrier MC of FIG. 7.

Although the mask carrier MC is described as having a slot in each of its four sides, this is not essential. The mask carrier MC may, for example, have a slot in two sides or in three sides.

Although rotation of the mask MA has been described in relation to rotation of the mask carrier MC, it will be appreciated that any form of rotation is suitable. For example, a user of the apparatus could manually load the mask MA into the mask storage area in a specific initial orientation, which would ensure that the substrate is exposed to a particular pattern A, B, C, D on the mask MA. Alternatively, the lithographic apparatus could be modified to allow the support structure MT to rotate, or even to facilitate the rotation of masks within the mask storage area 10. However, the lithographic apparatus may be substantially standard (i.e. unmodified), in order to reduce the cost of producing the apparatus and also to simplify the operation of the apparatus.

In the mask MA described above, four patterned areas A, B, C, D are provided on the mask MA. It will be appreciated that any number of patterns may be provided on the mask MA, and in any suitable configuration. For example, the mask may be provided with two, three or more patterns. In an embodiment, the only restriction is that the patterns are configured so that the mask can be rotated to bring a single pattern (or substantially a single pattern) into a position where the pattern can be projected onto the substrate (e.g. bringing a desired pattern into the projected periphery 2 of the projection system). For example, each pattern will have a center. The mask may be rotationally symmetric with respect to the pattern centers. This means that as the mask is rotated, and for a given degree of rotation, the pattern centers will align with the pattern centers before the mask was rotated. It can be seen from FIG. 4a that the mask MA is rotationally symmetric, in that for each 90° rotation of the mask, the centers of the patterns align with pattern centers before rotation.

In FIG. 4a, the pattern areas A, B, C, D are rectangular in shape. The patterned areas are arranged so that they form a chain of patterns extending around the center of the mask MA (i.e. the end of one rectangle is adjacent the end of another rectangle). This arrangement is advantageous when the patterns are elongate in shape (e.g. like a rectangle), as otherwise two elongate shapes may not be able to fit end-to-end on the mask. By arranging the patterns in a chain, the amount of wasted space on the mask (i.e. the unpatterned regions) is reduced, and more patterns may be located on the mask. Other embodiments not described here may adopt the same chain arrangement to maximize the number of patterns on the mask, and reduce the wasted space.

In the above description, the flip-chip bumping process has been described in terms of the use of solder. The term ‘solder’ is intended to include any suitable metal or alloy, and includes (but is not limited to) Eutectic 63Sn/37Pb solder, high lead solder, 95Pb5Sn, Tin, SnCuAg, SnAg3.5, SnCu, gold or copper. Other suitable materials may be used, and such materials will be known to those skilled in the art. The data contained in or directed to by identifier 3 could include an indication of which material is to be used for a given batch of substrates.

Although specific reference may be made in this text to the use of flip-chip bumping for ICs, it should be understood that the invention described herein may have other applications, such as flip-chip bumping for integrated optical systems, guidance and detection patterns for magnetic domain memories, liquid-crystal displays (LCDs), thin-film magnetic heads, etc. In general where the above description refers to an IC (or ICs), it will be understood that this is intended to include a device (or devices), which may or may not be an IC.

It will be appreciated that the mask described herein (i.e. with a plurality of patterns), as well as the method of using the mask (i.e. rotating the mask) may be used in any suitable lithographic apparatus and method, and not those restricted to flip-chip bumping. For example, the method and apparatus described herein may be used in any lithographic apparatus or method where the use of a plurality of patterns on a single mask is suitable (e.g. low resolution lithography, as described above).

While specific embodiments of the invention have been described above, it will be appreciated that the invention may be practiced otherwise than as described. The description is not intended to limit the invention, and the invention is only limited by the claims that follow.

1. A method of projecting a pattern onto a substrate, comprising:
rotating a mask having a plurality of patterns provided thereon, to select a pattern to be projected onto a substrate;
using the selected pattern to impart a beam of radiation with a pattern in its cross-section corresponding to the selected pattern; and
projecting the patterned beam of radiation onto a target portion of the substrate.

2. The method of claim 1, further comprising loading the mask onto a mask support, where the mask is used to impart the projection beam with the pattern corresponding to the selected pattern.

3. The method of claim 2, comprising rotating the mask before loading the mask onto the mask support.

4. The method of claim 2, further comprising, in order to change the selected pattern, unloading the mask from the mask support and, before loading the mask back onto the mask support, rotating the mask.

5. The method of claim 1, further comprising taking the mask from a mask storage area and loading the mask onto a mask support.

6. The method of claim 5, comprising transporting the mask between the mask storage area and the mask support in a mask carrier.

7. The method of claim 6, comprising rotating the mask carrier to effect rotation of the mask.

8. The method of claim 5, comprising rotating the mask before loading the mask into the mask storage area.

9. The method of claim 1, comprising rotating the mask automatically.

10. The method of claim 9, comprising rotating the mask using a robot handler.

11. The method of claim 1, comprising rotating the mask manually.

12. A lithographic apparatus, comprising:
a support configured to support a patterning device, the patterning device arranged to impart a beam of radiation with a pattern in its cross section;
a projection system configured to project the patterned beam onto a target portion of a substrate; and
a rotational mechanism configured to rotate the patterning device.

13. The apparatus of claim 12, wherein the center of the patterning device and of an imaging field of the projection system are offset from one another.

14. The apparatus of claim 12, wherein the rotational mechanism comprises a robot handler configured to rotate the patterning device.

15. The apparatus of claim 12, wherein the rotational mechanism comprises the support structure configured to rotate the patterning device.

16. A mask carrier, the mask carrier being formed from a container provided with a plurality of slots to load or unload a mask into or out of the mask carrier.

17. The mask carrier of claim 16, wherein the slots are on different sides of the container.

18. The mask carrier of claim 17, wherein the container comprises three slots.

19. The mask carrier of claim 18, wherein the container comprises four slots.

20. A lithographic mask comprising more than two patterns.

21. The mask of claim 20, wherein the mask comprises four patterns.

22. The mask of claim 20, wherein the patterns are offset from a center of the mask.

23. The mask of claim 20, wherein the patterns are arranged around a center of the mask.

24. The mask of claim 20, wherein each pattern has a center, and the mask is rotationally symmetric with respect to the pattern centers.

25. The mask of claim 20, wherein the patterns form a chain of patterns extending around a center of the mask.
